(19) United States
(12) Patent Application Publication
(10) Pub. No.: US 2025/0393160 A1
(43) Pub. Date: Dec. 25, 2025

(54) HEAT DISSIPATION PLATE, CIRCULATION COOLING DEVICE, AND CIRCULATION COOLING SYSTEM

(71) Applicant: Fulian Precision Electronics (Tianjin) Co., LTD., Tianjin (CN)

(72) Inventors: TSUNG-LIN LIU, Neihu (TW); CHUN-WEI LIN, New Taipei (TW); WEI-YU CHEN, New Taipei (TW); CHIA-NAN PAI, New Taipei (TW)

(21) Appl. No.: 18/964,822

(22) Filed: Dec. 2, 2024

(30) Foreign Application Priority Data
Jun. 24, 2024 (CN) 202410821701.5

(51) Int. Cl. H05K 7/20

(52) U.S. Cl. CPC H05K 7/20254; H05K 7/20263; H05K 7/20272; H05K 7/20772

(57) ABSTRACT

A heat dissipation plate for cooling a heat-generating component includes a heat dissipation body, the heat dissipation body defines a cavity, an inlet and an outlet, the inlet and the outlet communicating with the cavity; the heat dissipation body includes a heat-conducting surface, a heat-dissipating surface, and side connecting surfaces, the heat-conducting surface and the heat-dissipating surface are arranged opposite each other, the heat-conducting surface, the heat-dissipating surface, and the side connecting surfaces enclose the cavity, the inlet is provided on the side connecting surface; the outlet is provided on the heat-dissipating surface and/or the side connecting surface, the heat-conducting surface is configured to contact the heat-generating component, the inlet is configured to introduce a heat dissipation medium into the cavity; the heat dissipation medium inside the cavity is configured to absorb heat and is discharged through the outlet.

### FIELD

The present application relates to heat dissipation for electronic devices, particularly to a heat dissipation plate, a circulation cooling device, and a circulation cooling system.

### BACKGROUND

Servers may be immersed into a cooling medium for heat dissipation.

However, the server has multiple different components. Amount of heat generated by different components may also be different. When the cooling medium flows over the components, it may lead to insufficient cooling for components generating more heat or waste for components generating less heat.

### BRIEF DESCRIPTION OF THE DRAWINGS

Implementations of the present technology will now be described, by way of example only, with reference to the attached figures, wherein:

FIG. 1 is a diagrammatic view of a circulation cooling system according to an embodiment of the present application.

FIG. 2 is a diagrammatic view of an embodiment of a circulation cooling device of the circulation cooling system shown in FIG. 1.

FIG. 3 is a diagrammatic view of an embodiment of a heat dissipation plate of the circulation cooling device shown in FIG. 2.

FIG. 4 is a diagrammatic view of a heat dissipation plate according to another embodiment of the present application.

FIG. 5 is a diagrammatic view of a heat dissipation plate according to yet another embodiment of the present application.

FIG. 6 is a diagrammatic view of a heat dissipation plate according to still another embodiment of the present application.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain portions have been exaggerated to better illustrate details and features of the present disclosure.

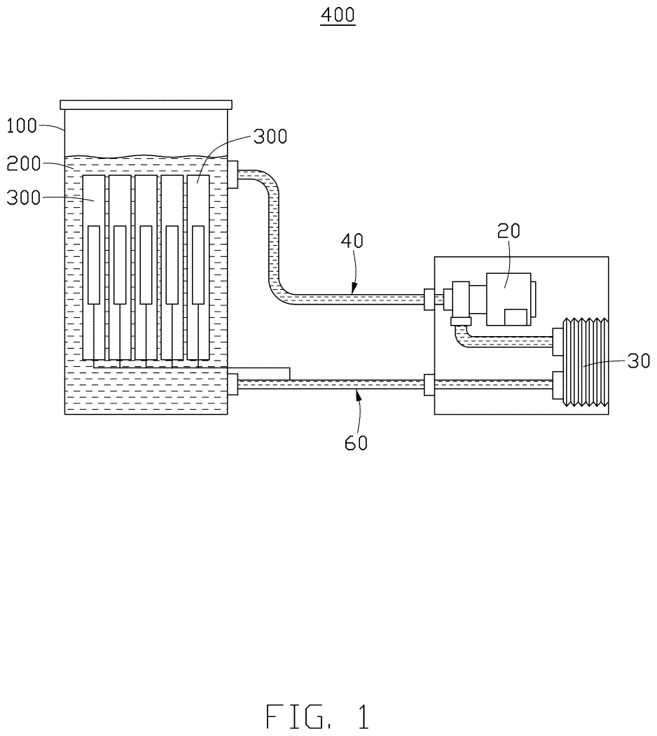

Referring to FIG. 1, a circulation cooling system 400 is provided according to an embodiment of the present application. The circulation cooling system 400 includes a circulation cooling device 100 and a heat dissipation medium 200 accommodated in the circulation cooling device 100. The circulation cooling system 400 is configured to dissipate heat generated from an electronic device 300. The heat dissipation medium 200 is in contact with the electronic device 300 and absorbs the heat generated by the electronic device 300. The circulation cooling device 100 accommodates the electronic device 300 and conducts the heat to an external environment. In one embodiment, the heat dissipation medium 200 is an insulating cooling liquid, and the electronic device 300 is a server. In other embodiments, the heat dissipation medium 200 may be a liquid metal, a phase change material, a superconducting material, or a biological media. The circulation cooling device 100 may also be applied in fields such as nuclear reactors, electronic devices, magnetic resonance imaging, and biomedical engineering.

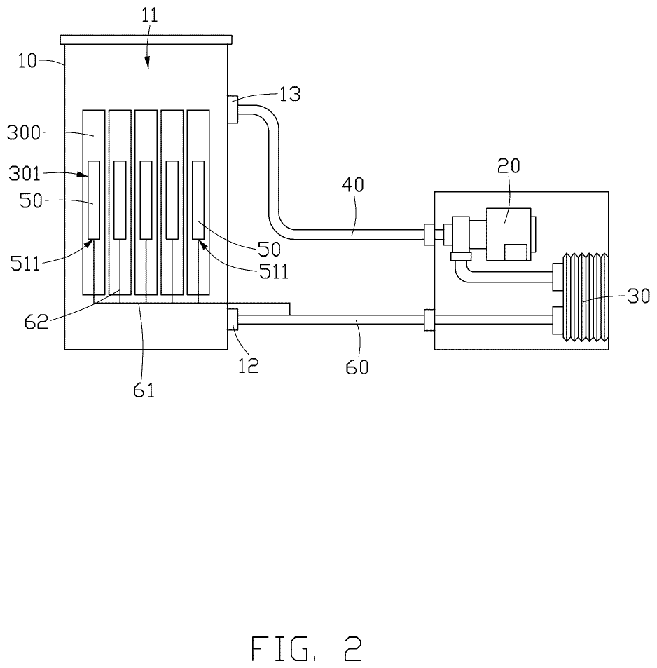

Referring to FIGS. 1 and 2, the circulation cooling device 100 includes a housing 10, a circulation driving component 20, and a heat exchanger 30. The circulation driving component 20 and the heat exchanger 30 are arranged outside the housing 10. The heat dissipation medium 200 is placed inside the housing 10. The housing 10 defines a receiving space 11, an input port 12, and an output port 13. The input port 12 is located at the bottom of the housing 10 and communicates with the receiving space 11. The output port 13 is located at the top of the housing 10 and communicates with the receiving space 11. The receiving space 11 accommodates the electronic device 300 and the heat dissipation medium 200 therein. The electronic device 300 is immersed in the heat dissipation medium 200. The circulation driving component 20 is in air communication with the input port 12 and the output port 13, and can drive the heat dissipation medium 200 to circulate inside and outside the housing 10. The heat exchanger 30 is connected between the output port 13 and the circulation driving component 20, and can exchange heat with the heat dissipation medium 200 that is outside the housing 10, thereby lowering the temperature of the heat dissipation medium 200. In one embodiment, the circulation driving component 20 is a pump. The heat exchanger 30 is one of a plate heat exchanger, a shell-and-tube heat exchanger, a double-pipe heat exchanger, or a finned heat exchanger.

When in use, the electronic device 300 generates heat. Inside the housing 10, the heat dissipation medium 200 flows from bottom to top through the electronic device 300 and absorbs heat from the electronic device 300, thus the temperature of the heat dissipation medium 200 increases. The heat dissipation medium 200 with higher-temperature is introduced into the heat exchanger 30 by the circulation driving component 20 and is cooled. The dissipation medium 200 with lower-temperature heat is then driven back into the housing 10 by the circulation driving component 20.

In one embodiment, the circulation cooling device 100 further includes an output pipe 40 and an input pipe 60. The output pipe 40 is connected the output port 13 and the circulation driving component 20. The input pipe 60 is connected the input port 12 and the circulation driving component 20. The heat exchanger 30 is arranged on the input pipe 60. The output pipe 40 allows the heat dissipation medium 200 with higher-temperature to flow out from the top of the housing 10. A portion of the input pipe 60 allows the heat dissipation medium 200 with lower-temperature to flow into the bottom of the housing 10, and another portion of the input pipe 60 guides the heat dissipation medium 200 into the heat exchanger 30 for cooling.

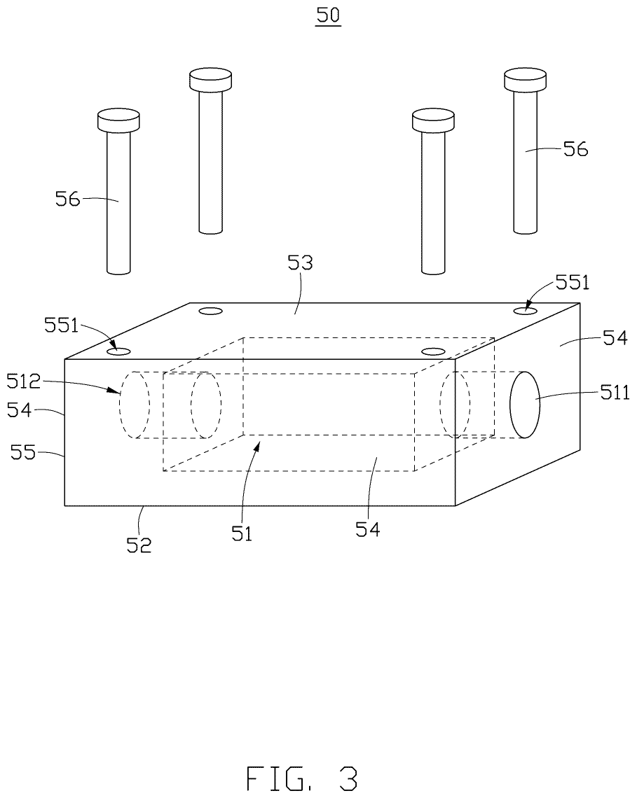

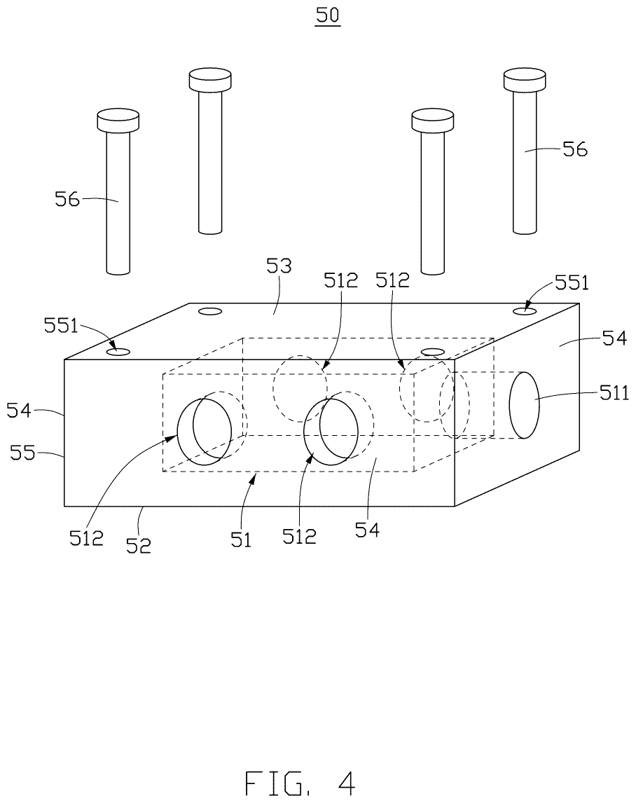

Referring to FIG. 3, in one embodiment, the circulation cooling device 100 further includes multiple heat dissipation plates 50. The electronic device 300 includes multiple heat-generating components 301. One side of each heat dissipation plate 50 is attached to one heat-generating component 301. Each heat dissipation plate 50 communicates with the heat exchanger 30. Referring to FIG. 4, the heat dissipation plate 50 defines a cavity 51, an inlet 511 and an outlet 512. The inlet 511 and the outlet 512 communicate with the cavity 51. The heat dissipation plate 50 includes a heat-conducting surface 52, a heat-dissipating surface 53, and multiple side connecting surfaces 54. The heat-conducting surface 52 and the heat-dissipating surface 53 are opposite to each other. The side connecting surfaces 54 are perpendicular connected between the heat-conducting surface 52 and the heat-dissipating surface 53. The heat-conducting surface 52, the heat-dissipating surface 53, and the side connecting surfaces 54 cooperatively define the cavity 51. The heat-conducting surface 52 is attached to the heat-generating component 301. The inlet 511 is located on one side connecting surface 54, and the outlet 512 is located on an opposite side connecting surface 54, making the flow direction of the heat dissipation medium 200 into and out of the cavity 51 to be parallel to each other. When the flow direction of the heat dissipation medium 200 into the cavity 51 is parallel to the flow direction of the heat dissipation medium 200 out the cavity 51, the pressure inside the cavity 51 is reduced. The inlet 511 communicates with the heat exchanger 30 to introduce the heat dissipation medium 200 with lower-temperature into the cavity 51. The heat generated by the heat-generating component 301 is conducted through the heat-conducting surface 52 to the heat dissipation medium 200 inside the cavity 51, such that the heat dissipation medium 200 is heated. The heated heat dissipation medium 200 is discharged through the outlet 512 into the receiving space 11. This allows the heat generated by the heat-generating component 301 to be quickly transferred and reducing abnormal temperature rises due to heat accumulation. In one embodiment, the heat-generating components 301 include Central Processing Units (CPUs), Graphics Processing Units (GPUs), memory modules, Solid-State Drives (SSDs), Power Supply Units (PSUs), Network Interface Cards (NICs), etc.

The heat dissipation plate 50 provided in the present application uses the heat dissipation medium 200 to cool the heat-generating components 301 with higher heat output, thereby improving cooling efficiency. The heat dissipation plate 50 increases the utilization rate of the heat dissipation medium 200 and reduces the energy consumption of the circulation cooling device 100. Additionally, the inlet 511 disposed on one side connecting surface 54 and the outlet 512 on the opposite side connecting surface 54 of the heat dissipation plate 50 reduce the pressure of the heat dissipation medium 200 inside the cavity 51, thereby further reducing the workload of the circulation driving component 20.

Referring to FIG. 4, in another embodiment, the heat dissipation plate 50 is substantially cuboid. The four side connecting surfaces 54 are connected to each other, and two adjacent side connecting surfaces 54 are perpendicular to each other. The inlet 511 is located one side connecting surface 54. Multiple outlets 512 are symmetrically arranged on the two side connecting surfaces 54 adjacent to the inlet 511. Thus, the flow direction of the heat dissipation medium 200 into the cavity 51 is substantially perpendicular to the flow direction out of the cavity 51, thereby further reducing pressure inside the cavity 51.

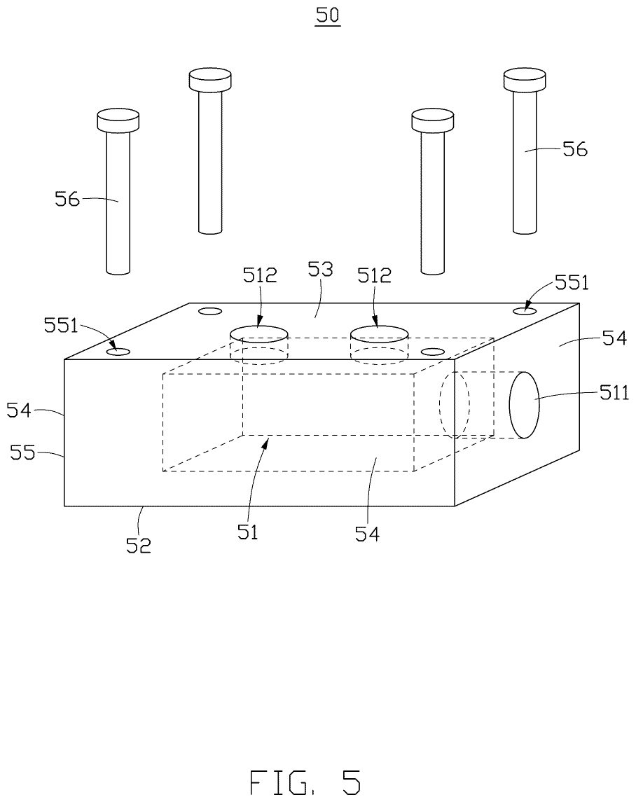

Referring to FIG. 5, in yet another embodiment, the heat dissipation plate 50 is substantially cuboid. The four side connecting surfaces 54 are connected to each other, and two adjacent side connecting surfaces 54 are perpendicular to each other. The inlet 511 is on one side connecting surface 54. Multiple outlets 512 are arranged on the heat-dissipating surface 53. Thus, the flow direction of the heat dissipation medium 200 into the cavity 51 is substantially perpendicular to the flow direction out of the cavity 51, thereby reducing preheating effects on other components. For example, preheating of heat-sensitive components around the heat-generating component 301, such as CPUs and GPUs, are reduced.

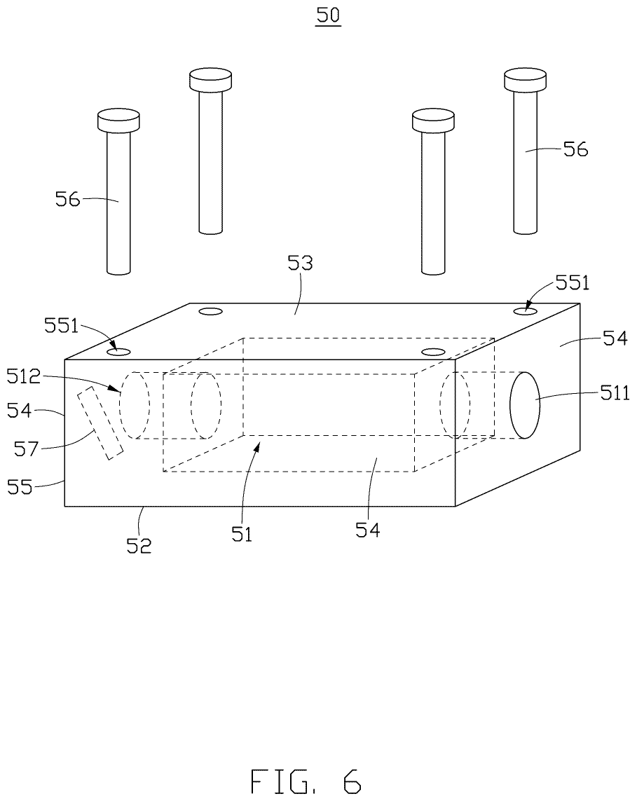

Referring to FIG. 6. in another embodiment, the heat dissipation plate 50 includes a flow guide plate 57. The flow guide plate 57 is rotatably arranged at the outlet 512. The flow guide plate 57 is configured to change the direction of the heat dissipation medium 200 flowing out of the cavity 51. The flow guide plate 57 allows for redistribution of heat distribution and further reduces the preheating of heat-sensitive components.

Referring to FIG. 2, in this embodiment, the input pipe 60 includes a main pipeline 61 and branch pipelines 62. The main pipeline 61 is connected the input port 12 and the circulation driving component 20. The heat exchanger 30 is arranged on the main pipeline 61. One end of each branch pipeline 62 is connected to a portion of the main pipeline 61 between the heat exchanger 30 and the input port 12. The other end of each branch pipeline 62 is connected to the inlet 511. Each branch pipeline 62 includes a convergence portion 621 and multiple lateral portions 622 connected to the convergence portion 621. The end of the convergence portion 621 away from the lateral portions 622 is connected to the main pipeline 61. Each lateral portion 622 is connected to the inlet 511 of one heat dissipation plate 50. Thus, the flow distribution capability of the heat dissipation medium 200 is enhanced, thereby improving the uniformity and efficiency of the circulation cooling system 400.

Referring to FIG. 3, in one embodiment, the heat dissipation plate 50 further includes a heat dissipation body 55 and a fixing member 56. The heat dissipation body 55 is substantially square. The cavity 51, the inlet 511, and the outlet 512 are all provided in the heat dissipation body 55. The heat dissipation body 55 also defines fixing holes 551, and the fixing holes 551 are misaligned with the inlet 511 and the outlet 512. The fixing member 65 passes through the fixing holes 551. One end of the fixing member 65 extends into the electronic device 300, and the other end of the fixing member 65 is abutted against the heat dissipation body 55. The fixing member 65 ensures that the heat-conducting surface 52 can be closely attached to the heat-generating component 301. Thus, the efficiency of heat conduction from the heat-generating component 301 to the heat-conducting surface 52 is improved. In one embodiment, the fixing member 65 is a screw.

In one embodiment, the material of the heat dissipation medium 200 includes one or more of fluorinated liquids, water, ethylene glycol solutions, and mineral oils. For example, the fluorinated liquid includes perfluorinated organic compounds with 5 to 18 carbon atoms per molecule.

The embodiments shown and described above are only examples. Many details are often found in the art such as the other features of the lens module 100. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the portions within the principles of the present disclosure up to, and including the full extent established by the broad general meaning of the terms used in the claims. It will therefore be appreciated that the embodiments described above may be modified within the scope of the claims.

What is claimed is:

1. A heat dissipation plate for cooling a heat-generating component, comprising:
a heat dissipation body defining a cavity, and comprising an inlet and an outlet, the inlet and the outlet communicating with the cavity; a heat-conducting surface, a heat-dissipating surface, and side connecting surfaces,
wherein the heat-conducting surface and the heat-dissipating surface are opposite to each other, the heat-conducting surface, the heat-dissipating surface, and the side connecting surfaces cooperatively define the cavity, the inlet is located on the side connecting surface, the outlet is located on the heat-dissipating surface and/or on the side connecting surface;
the heat-conducting surface is configured to be in contact with the heat-generating component, the inlet is configured to introduce a heat dissipation medium into the cavity, and the outlet is configured to discharge heat absorbed by the heat dissipation medium.

2. The heat dissipation plate of claim 1, further comprising a fixing member defining a plurality of fixing holes, wherein the plurality of fixing holes is misaligned with the inlet or the outlet, and the fixing member extends through the plurality of fixing holes to fix the heat dissipation plate to the heat-generating component.

3. The heat dissipation plate of claim 1, further comprising a flow guide plate movably arranged at the outlet, and configured to change a flow direction of the heat dissipation medium to flow out of the cavity.

4. A circulation cooling device for cooling an electronic device with a plurality of heat-generating components, the circulation cooling device comprising:
a housing defining a receiving space;
a plurality of heat dissipation plates arranged in the receiving space;
a circulation driving component, and a heat exchanger;
wherein the housing further defines an input port and an output port, each of the input port and the output port communicates with the receiving space, the receiving space is configured to accommodate the electronic device and a heat dissipation medium therein, the input port is configured to intake the heat dissipation medium to the receiving space, the output port is configured to discharge the heat dissipation medium to the receiving space;
wherein the plurality of heat dissipation plates is configured to connect to the plurality of heat-generating components, each of the plurality of heat dissipation plates comprises a heat dissipation body, the heat dissipation body defines a cavity, an inlet and an outlet, the inlet and the outlet communicate with the cavity; the heat dissipation body comprises a heat-conducting surface, a heat-dissipating surface, and side connecting surfaces, the heat-conducting surface and the heat-dissipating surface are opposite to each other, the heat-conducting surface, the heat-dissipating surface, and the side connecting surfaces cooperatively define the cavity, the inlet is located on the side connecting surface, the outlet is located on the heat-dissipating surface and/or the side connecting surface, the heat-conducting surface is configured to be in contact with the heat-generating component, the inlet is configured to introduce a heat dissipation medium into the cavity, and the outlet is configured to discharge heat absorbed by the heat dissipation medium, the outlet communicates with the receiving space;
wherein one end of the circulation driving component communicates with the output port, another end of the circulation driving component communicates with the input port and the inlet, the circulation driving component is configured to circulate the heat dissipation medium inside the receiving space;
wherein the heat exchanger is connected between the input port and the circulation driving component and is connected between the inlet and the circulation driving component, and the heat exchanger is configured to cool the heat dissipation medium.

5. The circulation cooling device of claim 4, wherein each of the plurality of heat dissipation plates further comprises a fixing member, the heat dissipation body defines a plurality of fixing holes, the plurality of fixing holes is misaligned with the inlet or the outlet, and the fixing member passes through the plurality of fixing holes to fix the heat dissipation plate to the heat-generating component.

6. The circulation cooling device of claim 4, wherein each of the plurality of heat dissipation plates further comprises a flow guide plate, the flow guide plate is movably arranged at the outlet, and the flow guide plate is configured to change a flow direction of the heat dissipation medium out of the cavity.

7. The circulation cooling device of claim 4, further comprising an output pipe and an input pipe, wherein the output pipe is connected to the output port and the circulation driving component, and the input pipe is connected to the circulation driving component, the input port, and the inlet.

8. The circulation cooling device of claim 7, wherein the input pipe comprises a main pipeline and a plurality of branch pipelines, the main pipeline is connected the circulation driving component and the input port, and the plurality of branch pipelines is connected to the main pipeline and the inlet.

9. The circulation cooling device of claim 8, wherein each of the plurality of branch pipelines comprise a convergence portion and a plurality of lateral portions connected to the convergence portion, one end of the convergence portion away from the lateral portions is connected to the main pipeline, and each of the plurality of lateral portions is connected to the inlet of a corresponding heat dissipation plate of the plurality of heat dissipation plates.

10. The circulation cooling device of claim 4, wherein the circulation driving component comprises a pump.

11. A circulation cooling system comprising a circulation cooling device and a heat dissipation medium, wherein the heat dissipation medium is configured to contact electronic devices and absorb heat generated by the electronic devices, the circulation cooling device accommodates the heat dissipation medium and conducts the heat to an external environment, the circulation cooling device comprises:
a housing defining a receiving space;
a plurality of heat dissipation plates arranged in the receiving space;
a circulation driving component; and
a heat exchanger,
wherein the housing further defines an input port and an output port, each of the input port and the output port communicates with the receiving space, the receiving space is configured to accommodate the electronic devices and the heat dissipation medium, the input port intakes the heat dissipation medium into the receiving space, the output port discharges the heat dissipation medium out of the receiving space;
wherein the plurality of heat dissipation plates is configured to connect to a plurality of heat-generating components of the electronic devices, each of the plurality of heat dissipation plates comprises a heat dissipation body, the heat dissipation body defines a cavity, an inlet and an outlet, the inlet and the outlet communicate with the cavity; the heat dissipation body comprises a heat-conducting surface, a heat-dissipating surface, and side connecting surfaces, the heat-conducting surface and the heat-dissipating surface are opposite to each other, the heat-conducting surface, the heat-dissipating surface, and the side connecting surfaces cooperatively define the cavity, the inlet is located on the side connecting surface, the outlet is located on the heat-dissipating surface and/or the side connecting surface, the heat-conducting surface is configured to be in contact with the plurality of heat-generating components, the inlet is configured to intakes the heat dissipation medium into the cavity, and the outlet is configured to discharge heat absorbed by the heat dissipation medium, the outlet communicates with the receiving space;
wherein one end of the circulation driving component communicates with the output port, and the other end communicates with the input port and the inlet, the circulation driving component is configured to drive the heat dissipation medium to flow inside the receiving space;
wherein the heat exchanger is connected between the input port and the circulation driving component, and connected between the inlet and the circulation driving component, the heat exchanger is configured to lower a temperature of the heat dissipation medium.

12. The circulation cooling system of claim 11, wherein the heat dissipation medium comprises a fluorinated liquid.

13. The circulation cooling system of clam 11, wherein each of the plurality of heat dissipation plates further comprises a fixing member, the heat dissipation body defines a plurality of fixing holes, the plurality of fixing holes is offset from the inlet or the outlet, the fixing member passes through the plurality of fixing holes to fix the heat dissipation plate to the plurality of heat-generating components.

14. The circulation cooling device of claim 11, wherein each of the plurality of heat dissipation plates further comprises a flow guide plate, the flow guide plate is movably arranged at the outlet, the flow guide plate is configured to change a flow direction of the heat dissipation medium to flow out of the cavity.

15. The circulation cooling device of claim 11, further comprising an output pipe and an input pipe, wherein the output pipe is configured to connect the output port and the circulation driving component, the input pipe is configured to connect the circulation driving component, the input port and the inlet.

16. The circulation cooling device of claim 15, wherein the input pipe comprises a main pipeline and a plurality of branch pipelines, the main pipeline is configured to connect the circulation driving component and the input port; the plurality of branch pipelines is configured to connect the main pipeline and the inlet.

17. The circulation cooling device of claim 16, wherein the branch pipelines comprise a convergence portion and a plurality of lateral portions connected to the convergence portion, one end of the convergence portion away from the lateral portions connects to the main pipeline, each of the plurality of lateral portions connects to the inlet of a corresponding heat dissipation plate of the plurality of heat dissipation plates.

18. The circulation cooling device of claim 11, wherein the circulation driving component comprises a pump.
